(19) United States
(12) Patent Application Publication
(10) Pub. No.: US 2024/0011146 A1
(43) Pub. Date: Jan. 11, 2024

(54) METHODS FOR FORMING COATING FILMS AND SUBSTRATE PROCESSING APPARATUS INCLUDING PARTS MANUFACTURED BY SUCH METHODS

(71) Applicant: Samsung Electronics Co., Ltd., Suwon-si (KR)

(72) Inventors: Seungjun LEE, Seoul (KR); Nongmoon HWANG, Seoul (KR)

(73) Assignee: Seoul National University R&DB Foundation, Seoul (KR)

(21) Appl. No.: 18/328,818

(22) Filed: Jun. 5, 2023

(30) Foreign Application Priority Data
Jul. 5, 2022 (KR) 10-2022-0082760

(51) Int. Cl. C23C 14/30; H01J 37/317; C23C 14/08; C23C 14/06; C23C 14/58

(52) U.S. Cl. CPC C23C 14/30; H01J 37/3178; C23C 14/083; C23C 14/0694; C23C 14/5806; H01J 2237/20214

(57) ABSTRACT

Provided herein are methods of forming a coating film that include providing a coating source including an orthorhombic vernier phase rare-earth element oxyfluoride and a part in a vacuum chamber, and performing a physical vapor deposition (PVD) process to form the coating film the part, wherein the coating film includes the orthorhombic vernier phase rare-earth element oxyfluoride. Apparatus including parts having coating films comprising an orthorhombic vernier phase rare-earth element oxyfluoride are also provided.

### CROSS-REFERENCE TO RELATED APPLICATION

This application is based on and claims priority under 35 U.S.C. § 119 to Korean Patent Application No. 10-2022-0082760, filed on Jul. 5, 2022, in the Korean Intellectual Property Office, the disclosure of which is incorporated by reference herein in its entirety.

### FIELD

The present inventive concept relates to methods of forming coatings or films, and to a substrate processing apparatus including parts manufactured by such methods. In particular, the present inventive concept relates to methods of forming coating films that may decrease the occurrence of corrosion caused by plasma and to substrate processing apparatus including parts including such coating films.

### BACKGROUND

In semiconductor manufacturing processes, an etching process may be used to form a pattern on a substrate. As the degree of integration of semiconductors increases, high aspect ratio contact (HARC) processes may be performed. In HARC processes, a dry etching process using plasma for forming a contact having a high aspect ratio may be performed in a relatively harsh environment, and fluorine plasma may be used for a high etch rate. Therefore, the plasma used in a plasma etching process may corrode surfaces of parts of a substrate processing apparatus performing the plasma etching process. As a consequence, the quality of semiconductor devices manufactured using the plasma etching process may be degraded as pollution particles become detached from surfaces of the parts, and due to this, the yield rate of the semiconductor manufacturing process may be reduced and the lifetime of important components in the apparatus may be shortened.

### SUMMARY

The present inventive concept provides methods of forming coating films that may provide improved plasma resistance and/or heat resistance.

The present inventive concept also provides substrate processing apparatus that include a coating film having improved plasma resistance and/or heat resistance.

According to an aspect of the present inventive concept, provided are methods of forming a coating film, the methods including the steps of providing a coating source including an orthorhombic vernier phase rare-earth element oxyfluoride and a part in a vacuum chamber; and performing a physical vapor deposition (PVD) process to form the coating film, wherein the coating film comprises the orthorhombic vernier phase rare-earth element oxyfluoride.

According to another aspect of the present inventive concept, provided are methods of forming a coating film, the methods including the steps of providing, in a vacuum chamber, a source container including a coating source comprising an orthorhombic vernier phase rare-earth element and a part opposite to the source container, and performing an electron beam physical vapor deposition (E-beam PVD) to form the coating film on the part, wherein the coating film comprises the orthorhombic vernier phase rare-earth element oxyfluoride (e.g., an orthorhombic vernier phase yttrium oxyfluoride having an experimental formula Y₁O₁₋ₙF₁₋₂ₙ, where 0.12≤n≤0.22), the E-beam PVD is performed by applying an electron beam, on which an XY sweep has been performed, to the coating source, the speed of the E-beam PVD is in a range of about 1 Å/s to about 5 Å/s, the E-beam PVD is performed at a base pressure of 0.7×10−5 Torr or less and at a process pressure of 1.5×10−5 Torr or less, and the part rotates at a speed in a range of about 3 rpm to about 10 rpm while the E-beam PVD is being performed. In some embodiments, the part is preheated to a temperature in a range of about 200° C. to about 350° C. and maintained at a temperature in a range of about 200° C. to about 350° C. while the E-beam PVD is being performed.

According to another aspect of the present inventive concept, there is provided a substrate processing apparatus including a processing chamber, a plasma formation device disposed in and/or on the processing chamber, and a plurality of substrate processing apparatus parts disposed in the processing chamber, wherein the substrate processing apparatus further includes a coating film disposed on an inner wall of the processing chamber and the plurality of substrate processing apparatus parts, wherein the coating film includes orthorhombic vernier phase rare-earth element oxyfluoride, and wherein the coating film is formed by using an electron beam physical vapor deposition (E-beam PVD).

### BRIEF DESCRIPTION OF THE DRAWINGS

Embodiments will be more clearly understood from the following detailed description taken in conjunction with the accompanying drawings in which:

FIG. 1 is a cross-sectional view schematically illustrating an electron beam physical vapor deposition (E-beam PVD) apparatus according to an embodiment of the invention.

FIG. 2 is a flowchart providing a method of forming a coating film according to an embodiment of the invention.

FIGS. 3A and 3B are diagrams schematically illustrating an E-beam application method in a method of forming a coating film according to an embodiment of the invention.

FIG. 4A is a diagram including X-ray diffraction (XRD) patterns of two comparative coating films and a coating film formed according to an embodiment of the invention, and FIG. 4B is a field emission transmission electron microscopy (FE-TEM) image of a coating film formed according to an embodiment of the invention.

FIG. 5A is a surface illumination spectrum of a coating film according to an embodiment of the invention; FIG. 5B is an ultraviolet (UV)-Vis-near infrared (NIR) spectrum of a coating film according to an embodiment of the invention; and FIG. 5C is a field emission scanning electron microscopy (FE-SEM) image of a coating film according to an embodiment of the invention.

FIG. 6 is a diagram including images of comparative coating films and a coating film according to an embodiment of the invention before and after a plasma etching process is performed thereon;

FIG. 7 is a graph showing binding energies of comparative coating films and a coating film according to an embodiment of the invention;

FIGS. 8A to 8C are graphs showing the concentration (%) of certain elements as a function of depth for the comparative coating films and a coating film according to an embodiment of the invention; and

FIG. 9 is a cross-sectional view illustrating a substrate processing apparatus according to an embodiment of the invention.

### DETAILED DESCRIPTION

Hereinafter, various embodiments will be described in detail with reference to the accompanying drawings. Like reference numerals refer to like elements in the drawings, and their repeated descriptions may be omitted. As used herein, “coating film” may be interchangeable with “coating” or “film.”

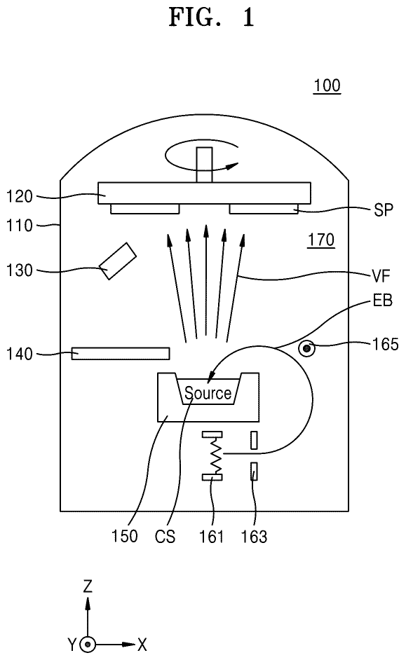

FIG. 1 is a cross-sectional view schematically illustrating an electron beam physical vapor deposition (E-beam PVD) apparatus 100 according to an embodiment of the invention.

Referring to FIG. 1, in some embodiments of the invention, the E-beam PVD apparatus 100 may include a vacuum chamber 110, a part holder 120, a monitoring device 130, a shutter 140, a source container 150, a filament 161, an E-beam accelerator 163, and an electromagnetic coil 165.

The vacuum chamber 110 may provide a processing space 170 therein. The processing space 170 may provide a space where a deposition process is performed on a part SP. The part holder 120, the monitoring device 130, the shutter 140, the source container 150, the filament 161, the E-beam accelerator 163, and the electromagnetic coil 165 may, in some embodiments, be provided in the processing space 170. In an embodiment, the vacuum chamber 110 may further include an exhaust pump (not shown). The exhaust pump may enable the processing space 170 of the vacuum chamber 110 to maintain a vacuum state.

In some embodiments, the part holder 120 may be disposed at an upper portion of the vacuum chamber 110. While a deposition process is being performed, the part SP may be attached on and supported by a bottom surface of the part holder 120. The part holder 120 may include a rotation driving device (not shown). The rotation driving device may rotate the part holder 120, and thus, the part SP supported by the part holder 120 may rotate while the deposition process is being performed. The part SP may be, for example, a wafer or a semiconductor substrate, but is not limited thereto.

In some embodiments, the monitoring device 130 may measure a thickness of a coating film formed on the part SP through an E-beam PVD process. The monitoring device 130 may include, for example, a quartz crystal microbalance (QCM) monitoring device, but is not limited thereto.

In some embodiments, the shutter 140 may be disposed between the part holder 120 and the source holder 150 in a Z direction. The shutter 140 may be configured to move horizontally in an X direction. A coating vapor VF obtained by vaporizing a coating source CS may or may not contact the part SP, or may contact a portion of the part SP, based on a position of the shutter 140. For example, when the shutter 140 is disposed to overlap the part holder 120 and/or the source container 150 in the Z direction, the coating vapor VF may be blocked by the shutter 140 and may not move toward the part SP. In this case, a coating layer may not be formed on the part SP. On the other hand, when the shutter 140 is disposed so that it does not overlap the part holder 120 and/or the source container 150 in the Z direction, the coating vapor VF may move toward the part SP. Accordingly, a coating layer may be formed on the part SP.

In some embodiments, the source container 150 may be disposed at a lower end portion of the vacuum chamber 110. A center of the source container 150, for example, may overlap a center of the part holder 120 in the Z direction. The source container 150 may include an opening portion that may accommodate the coating source CS.

In some embodiments, the filament 161, the E-beam accelerator 163, and the electromagnetic coil 165 may be provided in the processing space 170. The filament 161, the E-beam accelerator 163, and the electromagnetic coil 165 may be configured to generate electrons and apply the electrons to the coating source CS.

For example, the filament 161 may be supplied with high heat and may emit electrons. In some embodiments, the electrons emitted from the filament 161 may be accelerated by the E-beam accelerator 163. An acceleration voltage based on the E-beam accelerator 163 may be, for example, 10 kV. However, the inventive concept is not limited thereto, and the acceleration voltage may vary depending on energy of the electrons emitted from the filament 161.

The electromagnetic coil 165 may apply the electrons, accelerated by the E-beam accelerator 163, to the coating source CS. The vibration frequency and amplitude of the electromagnetic coil 165 may be adjusted by a control device (not shown) which will be described below, and thus, the electron application method may be varied. When the electrons are applied by the electromagnetic coil 165, the coating source CS may be vaporized, and thus, may form the coating vapor VF. The coating vapor VF may then be deposited onto the part SP, and thus, a coating film may be formed on the part SP.

In some embodiments, the E-beam PVD apparatus 100 may further include a control device (not shown). The control device may be configured to control the operation of the filament 161, the operation of the E-beam accelerator 163, and/or the operation of the electromagnetic coil 165. In some embodiments, the control device may be configured to control movement of the shutter 140 in the X direction. The control device may further include a transceiver for transmitting or receiving an electrical signal to or from the shutter 140, the filament 161, the E-beam accelerator 163, and/or the electromagnetic coil 165.

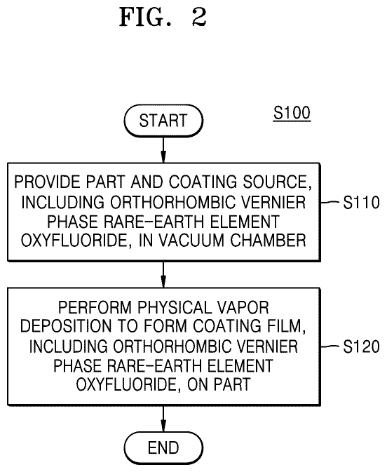

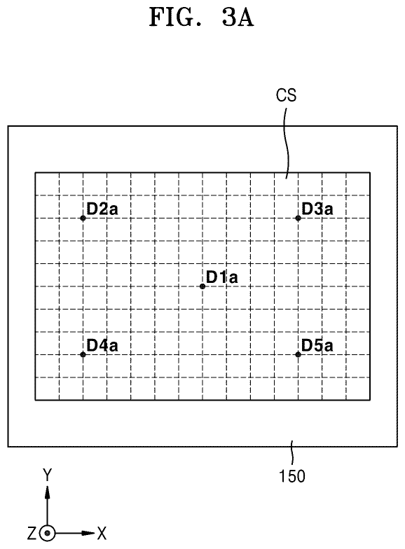

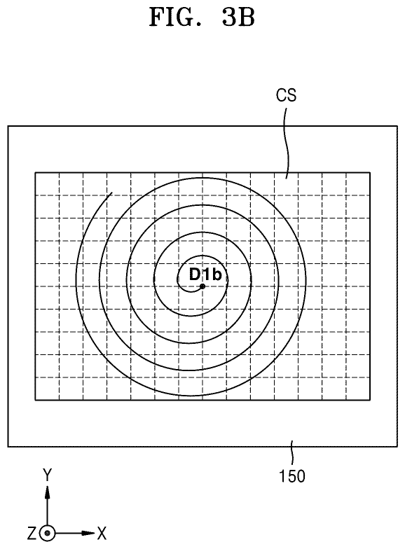

FIG. 2 is a flowchart illustrating a method (S100) of forming a coating film, according to an embodiment of the invention. FIGS. 3A and 3B are diagrams schematically illustrating an E-beam application method in a method of forming a coating film, according to an embodiment of the invention.

Referring to FIGS. 1 and 2, the method (S100) of forming a coating film may include a step (S110) of providing the coating source CS including an orthorhombic vernier phase rare-earth element oxyfluoride and the part SP in the vacuum chamber 110; and a step (S120) of performing an E-beam PVD process to form a coating film on the part SP, wherein the coating film includes the orthorhombic vernier phase rare-earth element oxyfluoride. The orthorhombic vernier phase rare-earth element oxyfluoride from the coating source is used to form the coating film including the orthorhombic vernier phase rare-earth element oxyfluoride, but the structure of the orthorhombic vernier phase rare-earth element oxyfluoride may vary somewhat between the coating source and the coating film.

In step S110, the coating source CS may be provided to an opening portion of the source container 150, and the part SP may be provided to and supported by a bottom surface of the part holder 120. In some embodiments, the coating source CS may include solid granules. In some embodiments, the coating source CS may include orthorhombic vernier phase rare-earth element oxyfluoride.

The orthorhombic vernier phase rare-earth element oxyfluoride may have an orthorhombic structure and may be a rare-earth element oxyfluoride having a unit cell configured in the one-dimensional superstructure of fluorite. For example, Y₇O₆F₉, is an orthorhombic vernier phase rare-earth element oxyfluoride. Y₇O₆F₉ may have a structure of a single YO⁺ layer disposed between F-layers of Y₇O₆F₉ vernier phase wherein the Y³⁺ ions are coordinated by four O²⁻ and three F-negative ions (YO₄F₃) and four O²⁻ and four F-negative ions (YO₄F₄).

In some embodiments, the orthorhombic vernier phase rare-earth element oxyfluoride may include at least one of an orthorhombic vernier phase yttrium oxyfluoride and an orthorhombic vernier phase lutetium oxyfluoride.

In some embodiments, when the orthorhombic vernier phase rare-earth element oxyfluoride is an orthorhombic vernier phase yttrium oxyfluoride, the orthorhombic vernier phase yttrium oxyfluoride may have an experimental formula of Y₁O₁₋ₙF₁₋₂ₙ (where 0.12≤n≤0.22).

For example, the orthorhombic vernier phase yttrium oxyfluoride may include at least one of Y₅O₄F₇, Y₆O₅F₈, Y₇O₆F₉, and Y₁₇O₁₄F₂₃.

In some embodiments, the method (S100) of forming a coating film may further include the step of preheating the part SP provided into the vacuum chamber 110. The preheating step may be performed before step S120 is performed and after step S110 is performed. In some embodiments, the part SP is preheated to a temperature in a range of about 200° C. to about 350° C.

In some embodiments, the temperature of the part SP may about 200° C. before step S120 is performed. When the temperature of the part SP rises to at least about 200° C., the coating film formed on the part SP in step S120 may have a crystalline structure.

In operation S120, in some embodiments, the coating film may be formed on the part SP by an E-beam PVD process. For example, an electron beam emitted from the filament 161 may be accelerated by the E-beam accelerator 163, and the accelerated electron beam may be applied to the coating source CS by the electromagnetic coil 165.

In some embodiments, the electron beam applied by the electromagnetic coil 165 may be an electron beam on which an XY sweep has been performed. Here, the term XY sweep means that the electron beam is not applied to one point of the coating source CS but is uniformly applied to a whole surface of the coating source CS. As described above, a vibration frequency and an amplitude of the electromagnetic coil 165 may be adjusted, and thus, the XY sweep may be performed.

In a case where a typical metal solid is used as a coating source in an E-beam PVD process, the metal solid may be melted as the temperature rises based on the application of an electron beam. The melted metal may then vaporize with additional application of the electron beam. When vaporization is performed in a melted state, the deposition speed may be relatively uniform even when an electron beam concentrates on only one point and is applied thereto.

In some embodiments, a method of forming a coating film may use an orthorhombic vernier phase rare-earth element oxyfluoride as a coating source. In this case, unlike a typical metal solid, as the electron beam is applied to the orthorhombic vernier phase rare-earth element oxyfluoride, the temperature may rise and sublimation may occur. That is, because sublimation occurs instead of melting and then vaporization, the deposition speed may not be as uniform when an electron beam concentrates on only one point and is applied thereto.

Therefore, in some embodiments, an electron beam may be uniformly applied to the whole surface of the coating source CS, and thus, the deposition speed may be relatively uniform. Hereinafter, this will be described in more detail with reference to FIGS. 3A and 3B in conjunction with FIG. 1. For convenience of description, an example is described where a coating source CS accommodated into the source container 150 has a rectangular shape in an X-Y plane, but the inventive concept is not limited thereto.

Referring to FIG. 3A, an electron beam EB may be applied to several points of the coating source CS. For example, the electron beam EB may be alternately applied to a center point D1a of the coating source CS and to the first to fourth vertexes D2a to D5a which are equidistant from the center point D1a in the X-Y plane. Here, the first to fourth vertexes D2a to D5a may be vertexes having a rectangular shape. In this case, the first vertex D2a and the fourth vertex D5a may form point symmetry with respect to the center point D1a, and the second vertex D3a and the third vertex D4a may form point symmetry with respect to the center point D1a. In FIG. 3A, it is illustrated that an electron beam is alternately applied to five points D1a to D5a of the coating source CS in the X-Y plane, but the inventive concept is not limited thereto. For example, an electron beam may be alternately applied to more or fewer points than five points (e.g., at least 2, at least 3, at least 4, at least 5, at least 6, at least 7, at least 8, at least 9, or at least 10 points, or 2, 3, 4, 5, 6, 7, 8, 9, 10 or more points, and any range defined therebetween) of the coating source CS in the X-Y plane.

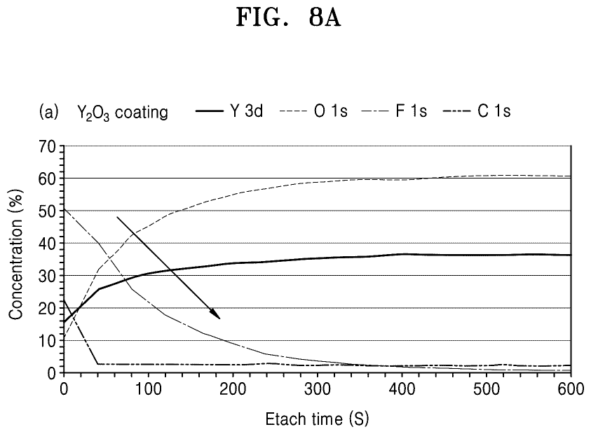

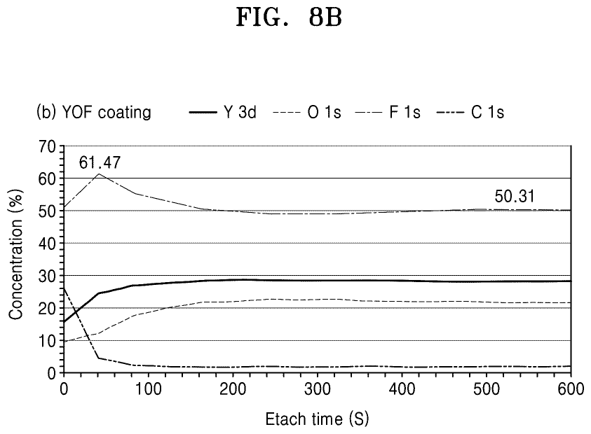

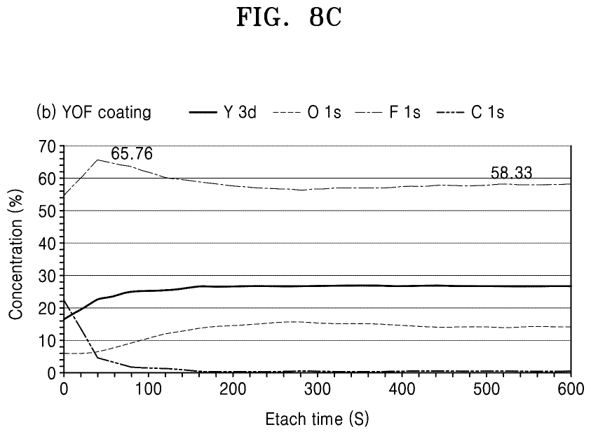

Referring to FIG. 3B, in some embodiments, an electron beam EB may be applied to the coating source CS to form a certain pattern. For example, an electron beam EB may be applied to the coating source CS along a line where the electron beam EB spreads in a spiral shape from a center point D1b of the coating source CS in an X-Y plane. However, the inventive concept is not limited thereto. For example, the electron beam EB may be applied to the coating source CS along a line which forms a FIG. 8-shape with respect to the center point D1b of the coating source CS in the X-Y plane.

Referring again to FIGS. 1 and 2, in operation S120, as an electron beam EB is applied, the coating source CS may be sublimated, and thus, may become a coating vapor VF. The coating vapor VF may be deposited on the part SP, and thus, a coating film may be formed.

In some embodiments, while operation S120 is being performed, the base pressure of the vacuum chamber 110 may be 0.7×10⁻⁵ Torr or less, and the process pressure may be 1.5×10⁻⁵ Torr or less. When the internal pressure of the vacuum chamber 110 is greater than 1.5×10⁻⁵ Torr, a mean free path of the coating vapor VF may not be sufficiently achieved, and due to this, a coating film may not be suitably formed.

In some embodiments, while operation S120 is being performed, the part SP may be maintained at a temperature in a range of about 200° C. to about 350° C. For example, in some embodiments, while operation S120 is being performed, the temperature of the part SP may be maintained at about 200° C. When a temperature of the part SP is less than about 200° C., a coating film formed on the part SP may have an amorphous structure. On the other hand, when a temperature of the part SP is more than about 350° C., the coating film may become stripped from the part SP due to a coefficient of thermal expansion (CTE) between the part SP and the coating film.

In some embodiments, in step S120, the deposition speed of the coating vapor VF may be in a range of about 1 Å/s to about 5 Å/s. For example, in some embodiments, in step S120, the deposition speed may be about 3 Å/s. When the deposition speed of the coating vapor VF is too fast, the density of the coating film formed on the part SP may be reduced. On the other hand, when the deposition speed of the coating vapor VF is too slow, the productivity for the process of forming a coating film may be reduced.

In some embodiments, while step S120 is being performed, a rotation speed of the part SP may be in a range of about 3 rpm to about 10 rpm. For example, in some embodiments, the rotation speed of the part SP may be about 5 rpm.

In some embodiments, the method (S100) of forming a coating film may further include the step of performing a post-deposition annealing process on the part SP with the coating film formed thereon. The step of performing the annealing process may be performed after step S120 is performed. In some embodiments, the annealing process may be performed at a temperature in a range of about 350° C. to about 450° C. In some embodiments, the post-deposition annealing process may be performed for a time in a range of about 90 min to about 150 min and under an oxygen atmosphere. When the annealing process is performed after step S120, the crystalline structure of coating film formed on the part SP may be improved, for example, by reducing or eliminating vacancies in the coating film.

In some conventional coating processes, a coating film may be deposited on a part by an atmosphere plasma spray (APS) process or a suspension plasma spray (SPS) process. When the coating film is formed by an APS process or an SPS process, the porosity of the coating film and the surface illumination may both be undesirably high. However, when a PVD process is used, a coating film having relatively low porosity and relatively low surface illumination, in addition to relatively good durability, may be formed. Therefore, even when a part SP is exposed to plasma, it may be protected by the coating film, and thus, the lifetime of the part may be extended.

In addition, in some comparative coating processes, a coating film may be formed on a part provided in a substrate processing apparatus by using a coating source including Y₂O₃, YF₃, or YOF. However, when the part is exposed to plasma in a plasma etching process, as the etching process is performed, a temperature of a coating film including Y₂O₃, YF₃, or YOF on the part may rise. As the temperature increases, a defect, such as a crack, may occur in the coating film due to the thermal stress. Such defects may create pollution particles that detach from the coating films. When this occurs, the quality of a semiconductor device manufactured using a plasma etching process may be degraded, and a yield rate of the semiconductor devices may be reduced, which may cause a reduction in the productivity of the semiconductor manufacturing process.

In some embodiments, a coating film formed according to a method of the invention comprising orthorhombic vernier phase rare-earth element oxyfluoride may be formed on the part SP by using an E-beam PVD process. Therefore, even when the part SP is exposed to plasma, defects and cracking of the coating film due to thermal stress may occur less than for a coating film including Y₂O₃, YF₃, or YOF. Accordingly, the occurrence of pollution particles may be reduced or eliminated, and thus, the quality of the semiconductor devices may be improved and the yield rate of the semiconductor devices may be improved, thereby improving the productivity of the semiconductor manufacturing process.

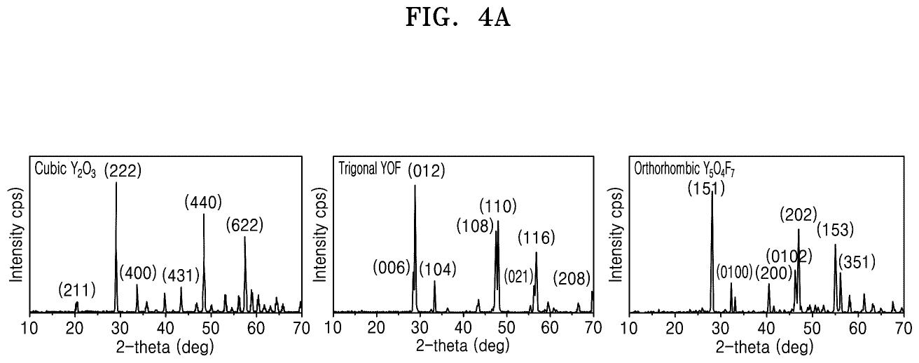

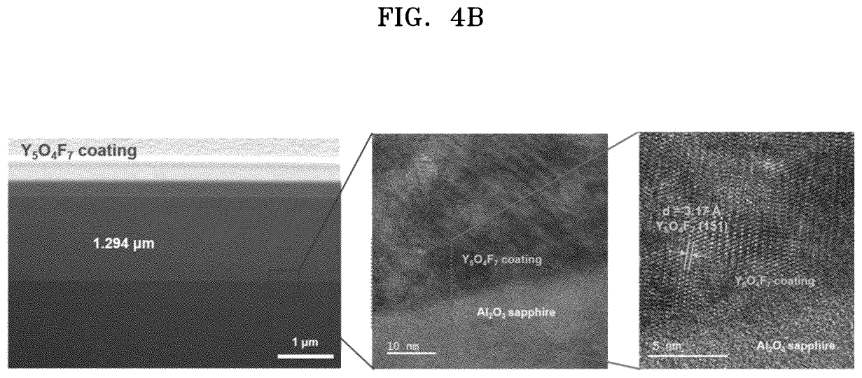

FIG. 4A is a diagram providing the X-ray diffraction (XRD) patterns of two comparative coating films and a coating film formed according to an embodiment, and FIG. 4B is a field emission transmission electron microscopy (FE-TEM) image of the coating film formed according to an embodiment of the invention. Specifically, FIG. 4A shows the XRD pattern of each of a Y₂O₃ coating film (left panel), a YOF coating film (center panel), and a Y₅O₄F₇ coating film (right panel).

Referring to FIG. 4A, each of the Y₂O₃ coating film, the YOF coating film, and the Y₅O₄F₇ coating film may have a peak in different 2-theta values. For example, in the XRD pattern, the Y₅O₄F₇ coating film may have a peak when the 2-theta value is 151, but the Y₂O₃ coating film and the YOF coating film may not have a peak when the 2-theta value is 151. Therefore, an XRD pattern of an arbitrary sample of a coating film may be evaluated to determine its 2-theta value.

Referring to FIG. 4B, it may be seen that a coating film formed according to an embodiment of the invention has a distance d (3.17A) between atoms when the 2-theta value is 151 in an FE-TEM image. That is, it may be seen that the coating film formed according to an embodiment of the invention is a Y₅O₄F₇ coating film, with reference to FIGS. 4A and 4B.

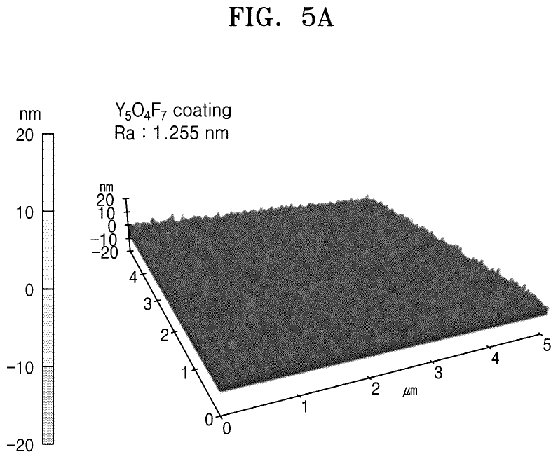

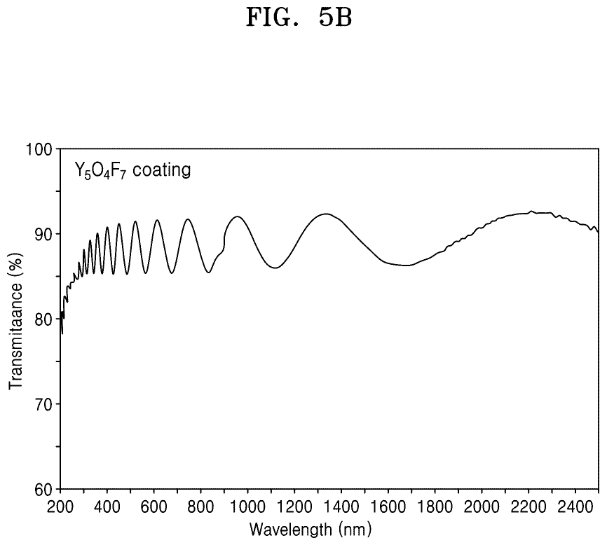

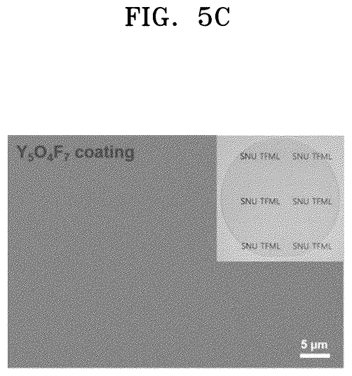

Hereinafter, properties of a coating film formed according to an embodiment of the invention will be described in more detail with reference to FIGS. 5A to 8C. FIGS. 5A to 8C will be described with reference to a coating film including an orthorhombic vernier phase rare-earth element oxyfluoride having a chemical formula “Y₅O₄F₇”, but the inventive concept is not limited thereto.

FIG. 5A provides a surface illumination plot of a coating film according to an embodiment of the invention. FIG. 5B provides an ultraviolet (UV)-Vis-near infrared (NIR) spectrum of the coating film according to an embodiment of the invention. FIG. 5C provides a field emission scanning electron microscopy (FE-SEM) image of another coating film according to an embodiment of the invention.

Referring to FIG. 5A, it may be seen that the arithmetic mean surface illumination Ra of a coating film including Y₅O₄F₇ is about 1.255 nm. When the surface illumination of a coating film is too high, pollution particles may more easily occur when the coating film is exposed to plasma during plasma etching. As seen in FIG. 5A, a surface illumination of a coating film formed according to an embodiment of the invention may have a relatively small value, such as about 1.255 nm. Therefore, even when the coating film is exposed to plasma, the occurrence of pollution particles from the coating film may be reduced or prevented. When the occurrence of pollution particles are reduced or prevented, the lifetime of parts having coating films formed thereon may be extended, the quality of the semiconductor devices manufactured by a substrate processing apparatus using the parts may be improved, and a yield rate of the semiconductor devices may be improved, thereby improving the productivity of the semiconductor manufacturing process.

Referring to FIG. 5B, it may be seen that a coating film including Y₅O₄F₇ may have a high transmittance value in a range of about 85% to about 90%. Based on the high transmittance of the coating film including Y₅O₄F₇, it may be seen that the coating film has a very low porosity and has a crystallographic isotopy. Moreover, referring to FIG. 5B, it may be seen that a fringe pattern appears in the UV-Vis-NIR spectrum of the coating film including Y₅O₄F₇. This may indicate that the surface illumination value of the coating film including Y₅O₄F₇ is small and the coating film has good uniformity. Therefore, even when the coating film including Y₅O₄F₇ is exposed to plasma, the occurrence of pollution particles from the coating film may be reduced or prevented. When the occurrence of pollution particles are reduced or prevented, the lifetime of parts with the coating film formed thereon may be extended, the quality of the semiconductor devices manufactured by a substrate processing apparatus using the parts may be improved, and a yield rate of the semiconductor devices may be improved, thereby improving the productivity of the semiconductor manufacturing process.

Referring to FIG. 5C, in the FE-SEM image, it may be seen that the transparency of the coating film including Y₅O₄F₇ is relatively high and no haze effect is present in the coating film. That the haze effect does not occur in the coating film may indicate that the composition of materials included in the coating film is uniform without being non-stoichiometric. The haze effect is a phenomenon wherein a coating film may appear unclear or hazy due to scattering of shorter wavelength(s). When the composition of the materials included in the coating film is uniform, the plasma resistance characteristics of the coating film may be relatively robust, and thus, even when the coating film is exposed to plasma, the occurrence of pollution particles from the coating film may be reduced or prevented. When the occurrence of pollution particles are reduced or prevented, the lifetime of parts with the coating film formed thereon may be extended, the quality of semiconductor devices manufactured by a substrate processing apparatus using the parts may be improved, and a yield rate of the semiconductor devices may be improved, thereby improving the productivity of the semiconductor manufacturing process.

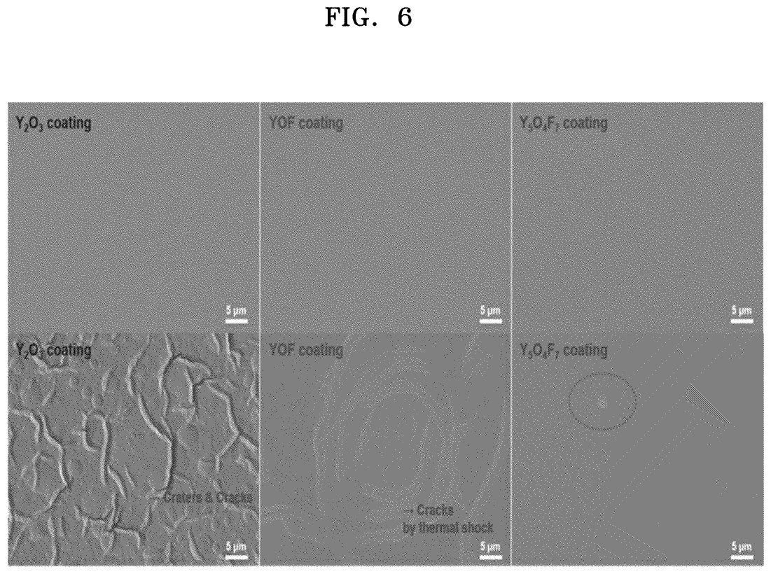

FIG. 6 shows a coating film including Y₂O₃ as a comparative example (left panel), a coating film including YOF as a comparative example (center panel), and a coating film including Y₅O₄F₇ according to an embodiment of the invention (right panel), before and after a plasma etching process is performed thereon. Each of the coating films shown in FIG. 6 has been formed through an E-beam PVD process, and the plasma etching process was performed for about 90 min by using a CHF₃ gas and argon (Ar) gas plasma.

Referring to FIG. 6, for the coating film of an embodiment of the invention (Y₅O₄F₇), defects such as cracks caused by thermal stress and craters caused by plasma etching are minimal or not seen, even after the plasma etching process is performed. On the other hand, it may be seen that, after the plasma etching process was performed, cracking occurred in the coating film including YOF, and significant cracks and craters caused by the plasma etching process occurred in the coating film including Y₂O₃. It may be seen in FIG. 6 that in a high temperature process environment, the coating film including Y₅O₄F₇ has better heat resistance and higher etch resistance to fluorine plasma than the coating film including YOF and the coating film including Y₂O₃.

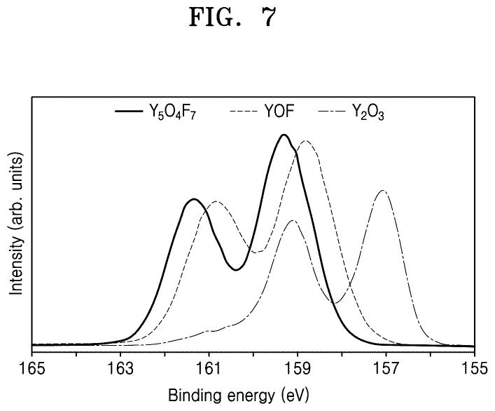

FIG. 7 is a diagram illustrating the binding energy of each of the comparative coating films and a coating film according to an embodiment. The binding energy of each of coating films has been obtained through X-ray photoelectron spectroscopy (XPS) analysis.

Referring to FIG. 7, it may be seen that the Y-F binding energy of a coating film including Y₅O₄F₇ in Y3d_{5/2} is 160.04 eV, the Y—F binding energy of the coating film including Y₅O₄F₇ in Y3d_{3/2} is 162.09 eV, the Y—O binding energy of the coating film including Y₅O₄F₇ in Y3d_{5/2} is 158.84 eV, and the Y—O binding energy of the coating film including Y₅O₄F₇ in Y3d_{3/2} is 160.89 eV. Moreover, it may be seen that the Y—F binding energy of a coating film including YOF in Y3d_{5/2} is 159.55 eV, the Y—F binding energy of the coating film including YOF in Y3d_{3/2} is 161.60 eV, the Y—O binding energy of the coating film including YOF in Y3d_{5/2} is 158.34 eV, and the Y—O binding energy of the coating film including YOF in Y3d_{3/2} is 160.40 eV. Finally, it may be seen that the Y—O binding energy of a coating film including Y₂O₃ in Y3d_{5/2} is 157.10 eV, and the Y—O binding energy of the coating film including Y₂O₃ in Y3d_{3/2} is 159.15 eV.

As may be seen in FIG. 7, the Y—O binding energy of the coating film including Y₅O₄F₇ is greater than the Y—O binding energy of the coating film including YOF and the Y—O bonding energy of the coating film including Y₂O₃. As the bonding energy of a coating film increases, the coating film may have a higher plasma etch resistance to the fluorine plasma used in reactive ion etching (RIE), and thus, it may be seen in FIG. 7 that the coating film including Y₅O₄F₇ has plasma etch resistance that is higher than the coating film including YOF and the coating film including Y₂O₃.

FIGS. 8A to 8C are graphs showing the concentration (%) with respect to depth for each of the comparative coating films and the coating film according to an embodiment of the invention. Specifically, FIGS. 8A and 8B are graphs respectively showing the concentration of a coating film including Y₂O₃ and the concentration of a coating film including YOF as a function of the depth of the coating film, and FIG. 8C is a graph showing the concentration of a coating film including Y₅O₄F₇ according to an embodiment of the invention as a function of its depth. Graphs of FIGS. 8A to 8C have been obtained through XPS depth profiling analysis, wherein the X axis indicates the time elapsed from a start time of XPS depth profiling, and the Y axis indicates a concentration of each coating film at a certain time. This may denote that movement is performed toward an inner portion of each coating film from a surface of each coating film as the etch time of the X axis increases.

Referring to FIG. 8A, in a coating film including Y₂O₃, it may be seen that the concentration of fluorine (F) decreases rapidly toward an inner portion of the coating film from the surface of the coating film.

Referring to FIGS. 8B and 8C, in each of the coating film including YOF and the coating film including Y₅O₄F₇, it may be seen that the concentration of fluorine (F) is maintained even in the inner portion thereof, but it may be seen that the concentration of fluorine (F) of the coating film including Y₅O₄F₇ is greater than the concentration of fluorine (F) of the coating film including YOF.

The coating film according to an embodiment of the invention may have fluorine (F) ions at a higher molar ratio than yttrium (Y) ions, compared to a comparative coating film including YOF or a comparative coating film including Y₂O₃. Therefore, the coating film according to an embodiment of the invention may have a fluorination layer having a higher density relative to comparative coating films. The fluorination layer may function as a protection layer that protects the coating film from fluorine plasma etching. Accordingly, a coating film according to an embodiment may include a fluorination layer having a higher density than the comparative coating films, and thus, may provide higher etch resistance to fluorine plasma used in plasma etching processes.

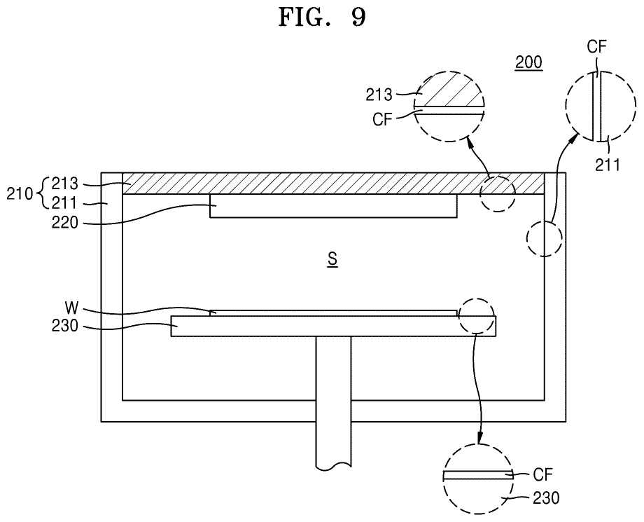

FIG. 9 is a cross-sectional view illustrating a substrate processing apparatus 200 according to an embodiment.

Referring to FIG. 9, the substrate processing apparatus 200 may include a chamber 210, a gas injection device 220, and a substrate supporting device 230.

In some embodiments, a plasma source of the substrate processing apparatus 200 may be, for example, a capacitively coupled plasma (CCP) source, an inductively coupled plasma (ICP) source, a helical plasma source, or a microwave plasma source, but is not limited thereto.

The chamber 210 may provide a processing space S therein. Several processes may be performed on a substrate W, in the processing space S. For example, a plasma etching process may be performed on a substrate W in the processing space S. The chamber 210 may have a rectangular shape but is not limited thereto.

In some embodiments, the chamber 210 may include a chamber body 211 and a window structure 213. The window structure 213 may include a material which enables the processing space S of the chamber 210 to be seen from the outside. For example, the window structure 213 may include tempered glass or a quartz.

In some embodiments, a coating film CF including orthorhombic vernier phase rare-earth element oxyfluoride may be disposed in at least a portion of each of an inner wall of the chamber body 211 and a bottom surface of the window structure 213. For example, the coating film CF may be disposed at the whole inner wall of the chamber body 211 and a portion of the bottom surface of the window structure 213 exposed in the processing space S.

In some embodiments, the orthorhombic vernier phase rare-earth element oxyfluoride may be an orthorhombic vernier phase yttrium oxyfluoride having an experimental formula, Y₁O₁₋ₙF₁₋₂ₙ, where 0.12≤n≤0.22. For example, the orthorhombic vernier phase yttrium oxyfluoride may include at least one of Y₅O₄F₇, Y₆O₅F₈, Y₇O₆F₉, and Y₁₇O₁₄F₂₃.

In some embodiments, the coating film CF including the orthorhombic vernier phase rare-earth element oxyfluoride may have a thickness in a range of about 0.01 m to about 100 m. For example, in some embodiments, the coating film CF may have a thickness of about 50 m. Here, the thickness is measured in the direction in which the inner wall of the chamber body 211 or the bottom surface of the window structure 213 is vertical to a surface contacting the coating film CF.

The gas injection device 220 may be disposed in the processing space S. In FIG. 9, it is illustrated that the gas injection device 220 is coupled to a lower portion of the window structure 213, but the inventive concept is not limited thereto. For example, the gas injection device 220 may be coupled to the chamber body 211. In this case, the coating film CF including the orthorhombic vernier phase rare-earth element oxyfluoride may be disposed on the whole bottom surface of the window structure 213 and the other inner wall, except the portion of the inner wall of the chamber body 211 coupled to the gas injection device 220. In some embodiments, the gas injection device 220 may be configured to supply gases needed for performing a process on the substrate W into the processing space S. In some embodiments, the gas injection device 220 may include, for example, a gas nozzle, a gas pipe flange, a gas distribution plate, and a shower head. In some embodiments, the coating film CF may be disposed on both sidewalls and the bottom surface of the gas injection device 220.

In some embodiments, the substrate supporting device 230 may be disposed under the gas injection device 220 in the processing space S. The substrate supporting device 230 may support the substrate W while processing is being performed on the substrate W. In some embodiments, the substrate supporting device 230 may include, for example, an electrostatic chuck (ESC). The coating film CF may be disposed on a portion of the top surface of the substrate supporting device 230 exposed in the processing space S.

The coating films CF disposed on the inner wall of the chamber body 211, the bottom surface of the window structure 213, and the top surface of the substrate supporting device 230 may be formed by the method (S100) of forming a coating film described above with reference to FIGS. 2, 3A, and 3B. The coating film CF may include an orthorhombic vernier phase rare-earth element oxyfluoride having relatively high plasma resistance and heat resistance, and thus, the inner wall of the chamber body 211, the bottom surface of the window structure 213, and the top surface of the substrate supporting device 230, where the coating films CF are disposed, may be reduced, or prevented from being corroded by plasma. Accordingly, pollution particles occurring due to corrosion caused by plasma may be reduced, and thus, the quality of the semiconductor devices manufactured through processing performed in the substrate processing apparatus 200 may be improved, and the yield rate of semiconductor devices may be improved, thereby improving the productivity the semiconductor device manufacturing process. Furthermore, parts, such as the chamber body 211 and the window structure 213, may be protected by the coating film, and thus, the lifetimes of such parts may increased.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A method of forming a coating film, the method comprising:
providing (a) a coating source comprising an orthorhombic vernier phase rare-earth element oxyfluoride and (b) a part, in a vacuum chamber; and
performing a physical vapor deposition (PVD) process using the coating source to form a coating film on the part,
wherein the coating film comprises the orthorhombic vernier phase rare-earth element oxyfluoride.

2. The method of claim 1, wherein the orthorhombic vernier phase rare-earth element oxyfluoride comprises one of an orthorhombic vernier phase yttrium oxyfluoride and an orthorhombic vernier phase lutetium oxyfluoride.

3. The method of claim 2, wherein the orthorhombic vernier phase rare-earth element oxyfluoride comprises an orthorhombic vernier phase yttrium oxyfluoride having an experimental formula of Y₁O₁₋ₙF₁₋₂n (where 0.12≤n≤0.22), and optionally wherein the orthorhombic vernier phase yttrium oxyfluoride comprises at least one of Y₅O₄F₇, Y₆O₅F₈, Y₇O₆F₉, and Y₁₇O₁₄F₂₃.

4. The method of claim 1, wherein the PVD is electron beam physical vapor deposition (E-beam PVD).

5. The method of claim 4, wherein the E-beam PVD is performed by using an XY sweep electron beam.

6. The method of claim 1, wherein, while the PVD is being performed, a base pressure of the vacuum chamber is 0.7×10⁻⁵ Torr or less, and a process pressure of the vacuum chamber is 1.5×10⁻⁵ Torr or less.

7. The method of claim 1, wherein the part is preheated at a temperature in a range of about 200° C. to about 350° C.

8. The method of claim 1, wherein a speed of the PVD is in a range of about 1 Å/s to about 5 Å/s.

9. The method of claim 1, further comprising annealing the coating film after the PVD.

10. The method of claim 9, wherein the annealing is performed at a temperature in a range of about 350° C. to about 450° C.

11. The method of claim 9, wherein the annealing is performed under an oxygen atmosphere for a time in a range of about 90 min to about 150 min.

12. A method of forming a coating film, the method comprising:
providing (a) a source container including a coating source comprising an orthorhombic vernier phase rare-earth element oxyfluoride and (b) a part opposite to the source container, in a vacuum chamber; and
performing an electron beam physical vapor deposition (E-beam PVD) to form a coating film on the part,
wherein the coating film comprises the orthorhombic vernier phase rare-earth element oxyfluoride, and wherein the orthorhombic vernier phase rare-earth element oxyfluoride optionally comprises orthorhombic vernier phase yttrium oxyfluoride having an experimental formula Y₁O₁₋ₙF₁₋₂ₙ (where 0.12≤n≤0.22),
wherein the E-beam PVD is performed by applying an electron beam, on which an XY sweep has been performed, to the coating source,
wherein a speed of the E-beam PVD is in a range of about 1 Å/s to about 5 Å/s,
wherein the E-beam PVD is performed at a base pressure of 0.7×10⁻⁵ Torr or less and a process pressure of 1.5×10⁻⁵ Torr or less, and
wherein the part rotates at a speed in a range of about 3 rpm to about 10 rpm while the E-beam PVD is being performed.

13. The method of claim 12, wherein the orthorhombic vernier phase yttrium oxyfluoride comprises at least one of Y₅O₄F₇, Y₆O₅F₈, Y₇O₆F₉, and Y₁₇O₁₄F₂₃.

14. The method of claim 12, further comprising performing an annealing process on the coating film after the E-beam PVD, wherein the annealing process is performed at a temperature in a range of about 350° C. to about 450° C. and wherein the annealing process is performed under an oxygen atmosphere for a time in a range of about 90 min to about 150 min.

15. The method of claim 12, further comprising preheating the part before the E-beam PVD is performed, wherein the part is preheated to a temperature in a range of about 200° C. to about 350° C. and wherein the part is maintained at a temperature in a range of about 200° C. to about 350° C. while the E-beam PVD is being performed.

16. The method of claim 15, wherein preheating the part comprises preheating the part to a temperature of about 200° C.

17. A method of forming a coating film, the method comprising:
providing substrate processing apparatus parts and a coating source comprising an orthorhombic vernier phase rare-earth element oxyfluoride, a processing chamber; and
performing an electron beam physical vapor deposition (PVD) process using the coating source to form a coating film on the substrate processing apparatus parts,
wherein the coating film comprises the orthorhombic vernier phase rare-earth element oxyfluoride, and
wherein the substrate processing apparatus parts are configured to perform substrate processing using a plasma, and the substrate processing apparatus parts are exposed to plasma during the substrate processing.

18. The method of claim 17, wherein the orthorhombic vernier phase rare-earth element oxyfluoride comprises an orthorhombic vernier phase yttrium oxyfluoride having an experimental formula Y₁O₁₋ₙF₁₋₂ₙ (where 0.12≤n≤0.22).

19. The method of claim 18, wherein the orthorhombic vernier phase yttrium oxyfluoride comprises at least one of Y₅O₄F₇, Y₆O₅F₈, Y₇O₆F₉, and Y₁₇O₁₄F₂₃.

20. The method of claim 17, wherein the substrate processing apparatus parts comprise a window structure and/or an electrostatic chuck.
